(19) United States
(12) Patent Application Publication
(10) Pub. No.: US 2013/0314842 A1
(43) Pub. Date: Nov. 28, 2013

(54) THIN FILM CONDENSER FOR HIGH-DENSITY PACKAGING, METHOD FOR MANUFACTURING THE SAME, AND HIGH-DENSITY PACKAGE SUBSTRATE INCLUDING THE SAME

(71) Applicant: KOREA INSTITUTE OF SCIENCE AND TECHNOLOGY, Seoul (KR)

(72) Inventors: Chong Yun KANG, Seoul (KR); Min Gyu KANG, Incheon (KR); Seok Jin YOON, Seoul (KR); Ji Won CHOI, Seoul (KR); Seung Hyub BAEK, Seoul (KR); Jin Sang KIM, Seoul (KR)

(73) Assignee: KOREA INSTITUTE OF SCIENCE AND TECHNOLOGY, Seoul (KR)

(21) Appl. No.: 13/677,664

(22) Filed: Nov. 15, 2012

(30) Foreign Application Priority Data
May 23, 2012 (KR) 10-2012-0054827

(51) Int. Cl. H01G 4/06; H05K 5/00

(52) U.S. Cl. CPC H01G 4/06; H05K 5/0091
USPC 361/303; 430/313; 361/820; 427/79

(57) ABSTRACT

Provided are a thin film condenser for high-density packaging, a method for manufacturing the same and a high-density package substrate. The thin film condenser for high-density packaging, includes: a support substrate; a lower electrode formed on the support substrate; a dielectric thin film formed on the lower electrode; and an upper electrode formed on the dielectric thin film. Provided also is a method for manufacturing the same. The high-density package substrate, includes: at least two stacked substrates; thin film condensers embedded in the stacked substrates; an internal connection electrode formed in the stacked substrates and connecting the thin film condensers in series or in parallel; a surface electrode formed on the surface of the outermost substrate among the stacked substrates and connected to the internal connection electrode; and an integrated circuit connected to the surface electrode via a bump.

### CROSS-REFERENCE TO RELATED APPLICATION

This application claims priority to Korean Patent Application No. 10-2012-0054827, filed on May 23, 2012, and all the benefits accruing therefrom under 35 U.S.C. §119, the contents of which in its entirety are herein incorporated by reference.

### BACKGROUND

1. Field

The present disclosure relates to a thin film condenser for high-density packaging, a method for manufacturing the same, and a high-density package substrate including the same. More particularly, the present disclosure relates to a thin film condenser capable of being embedded easily in a substrate without modifying the electrical and physical properties of a high-density package substrate and having excellent capacitance and dielectric properties. The present disclosure also relates to a method for manufacturing a thin film condenser for high-density packaging which allows the manufacture of the above-mentioned thin film condenser by a simple process at low cost, and to a high-density package substrate in which the thin film condenser is embedded.

2. Description of the Related Art

In general, 50% or more of the area of a printed circuit board (PCB) used currently in the field of electronic parts is occupied by passive devices. Particularly, capacitor devices occupy 60% or more of passive devices, and are used frequently for the purpose of decoupling, AC coupling, filtering and timing. Condensers used currently in electronic circuits mostly include electrolytic condensers, Mylar condensers, ceramic condensers and chip-type multilayer ceramic condensers (MLCC) for use in high-density packaging. Some producers have launched packaging condensers.

As the wireless communication market have grown rapidly with smart phones in the lead and portable instruments have become lightened, high-functionalized and complex, there has been an increasing need for high-density packaging and speed-up of electronic circuits. In addition, as the use of wireless communication instruments has increased and mass wireless information transfer technology has been increasingly on demand, applications of high-frequency electronic communication circuits have increased rapidly. Under these circumstances, there has been an increasing need for packaging technology to meet the requirements of the market with respect to high-frequency characteristics while using the existing PCBs.

Particularly, active studies have been conducted about novel technological methods to increase the integration degree of two-dimensional semiconductors and mobile communication devices. The most spotlighted technology in terms of improvement of the integration degree is increasing the integration degree of a chip through three-dimensional connection technology.

Recently, multi chip module (MCM), System in Package (SiP) and the like are one type of three-dimensional packaging technologies applied to portable electronic appliances and high-performance systems. In addition to a need for increasing the integration degree of a device, there has been a need for fabricating a plurality of chips having different characteristics and functions into one microsystem. Due to this, printed circuit boards in which a film condenser is embedded and condensers for high-density packaging capable of individual embedding have been developed.

According to the related art, methods for manufacturing condensers for high-density packaging may be classified broadly into methods including applying a polymer paste, methods including applying a ceramic filler and polymer resin in the form of a paste, and methods including inserting a dielectric thin film layer. By virtue of highly integrated packaging of a circuit and a decrease in connection length, the condensers for high-density packaging obtained by the above methods may overcome degradation of reliability of finished products caused by an increase in connection number through soldering or the like and by degradation of product quality resulting from a large connection length between devices at high frequency in the existing surface mounting devices and generation of electrically parasitic components.

For example, Korean Laid-Open Patent Publication No. 10-2007-0006642, and Japanese Laid-Open Patent Publication Nos. JP2009-295925, JP2005-50978, JP2004-235359, JP2007-66997 and JP2007-317938 disclose some technologies related with condensers for high-density packaging.

However, the condensers for high-density packaging and the manufacture method thereof according to the related art including the above references require deposition of a plurality of thin film layers, masking and etching to form an interconnection as the top of a device. Therefore, they have problems of high cost and low yield, since the internal structures for device connection are complicated and the condensers are realized only by repeating a complicated process such as photolithography many times. Moreover, since the condensers have a plurality of layers, it is difficult to package (embed) them in a high-density package substrate. This results in a change in electrical and physical properties of a high-density package substrate, and degradation of capacitance and dielectric properties.

### REFERENCES OF THE RELATED ART

### Patent Document

Korean Laid-Open Patent Publication No. 10-2007-0006642
Japanese Laid-Open Patent Publication No. JP2009-205925
Japanese Laid-Open Patent Publication No. JP2005-50978
Japanese Laid-Open Patent Publication No. JP2004-235359
Japanese Laid-Open Patent Publication No. JP2007-66997
Japanese Laid-Open Patent Publication No. JP2007-317938

### SUMMARY

The present disclosure is directed to providing a thin film condenser for high-density packaging, which is capable of being embedded in a substrate easily without changing the electrical and physical properties of a high-density package substrate, and has excellent capacitance and dielectric properties. The present disclosure is also directed to providing a method for manufacturing a thin film condenser for high-density packaging by a simple process at low cost, and a high-density package substrate in which the thin film condenser is embedded.

In one aspect, there is provided a thin film condenser for high-density packaging, including:

a support substrate;

a lower electrode formed on the support substrate;

a dielectric thin film formed on the lower electrode; and

an upper electrode formed on the dielectric thin film,

wherein the upper electrode includes two electrodes spaced apart from each other by a predetermined distance on the dielectric thin film.

In another aspect, there is provided a method for manufacturing a thin film condenser for high-density packaging, including:

forming a lower electrode on a support substrate;

forming a dielectric thin film on the lower electrode;

forming an upper electrode on the dielectric thin film; and

patterning the upper electrode to form two electrodes spaced apart from each other by a predetermined distance on the dielectric thin film.

The method may further include, after patterning the upper electrode, polishing the back surface of the support substrate to reduce the thickness of the support substrate. Particularly, the dielectric thin film may be formed to have a thickness of 50 nm-3 μm.

In still another aspect, there is provided a high-density package substrate, including:

at least two stacked substrates;

thin film condensers embedded in the stacked substrates;

an internal connection electrode formed in the stacked substrates and connecting the thin film condensers in series or in parallel;

a surface electrode formed on the surface of the outermost substrate among the stacked substrates and connected to the internal connection electrode; and

an integrated circuit connected to the surface electrode via a bump.

The thin film condenser for high-density packaging disclosed herein has a simple structure and is capable of being embedded in a high-density package substrate easily without changing the electrical and physical properties of the high-density package substrate. In addition, the thin film condenser for high-density packaging has excellent capacitance and dielectric properties.

Additionally, since the thin film condenser disclosed herein does not have a complicated structure that appears in the case of the thin film condenser for high-density packaging according to the related art but has a simple structure, it is manufactured with ease at low cost. Further, the high-density package substrate disclosed herein has thin film condensers packaged with high density, and thus has high packaging efficiency per unit area (or volume) and realizes a slimmed appearance.

### BRIEF DESCRIPTION OF THE DRAWINGS

The above and other aspects, features and advantages of the disclosed exemplary embodiments will be more apparent from the following detailed description taken in conjunction with the accompanying drawings in which:

FIG. 1 is a flow chart of the method for manufacturing a thin film condenser for high-density packaging according to an embodiment;

FIG. 2 is a perspective view of the thin film condenser for high-density packaging according to an embodiment; and

FIG. 3 is a plane view of the thin film condenser for high-density packaging according to an embodiment;

FIG. 4 is a schematic view illustrating the capacitance generated in the thin film condenser for high-density packaging according to an embodiment; and

FIG. 5 is a schematic sectional view of the high-density package substrate according to an embodiment.

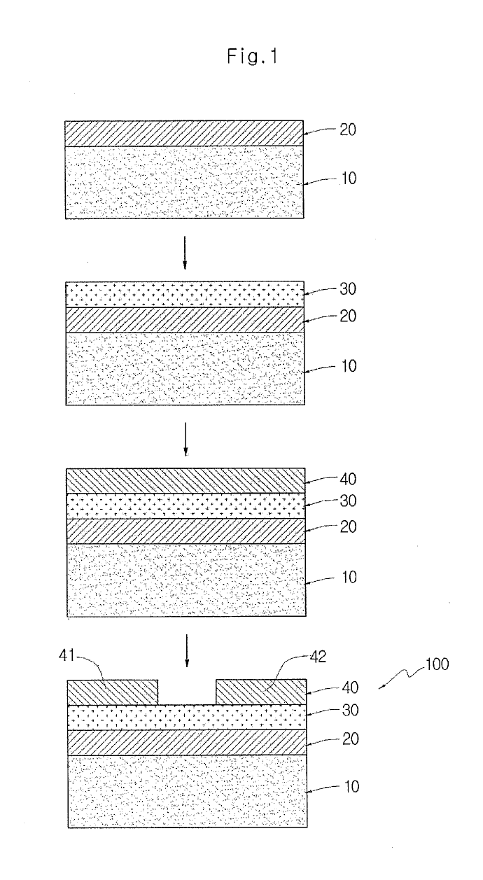

### DETAILED DESCRIPTION OF MAIN ELEMENTS

| | |
|---|---|
| 10: support substrate | 20: lower electrode |
| 30: dielectric thin film | 40: upper electrode |
| 41: first electrode | 42: second electrode |
| 100: thin film condenser | 110: stacked substrates |
| 120: internal connection electrode | 130: surface electrode |
| 140: bump | 150: integrated circuit |

### DETAILED DESCRIPTION

Exemplary embodiments now will be described more fully hereinafter with reference to the accompanying drawings, in which exemplary embodiments are shown.

The thin film condenser for high-density packaging according to an embodiment (abbreviated as ‘thin film condenser’ hereinafter) includes a support substrate 10, a lower electrode 20 formed on the support substrate 10, a dielectric thin film 30 formed on the lower electrode 20, and an upper electrode 40 formed on the dielectric thin film 30. In addition, the upper electrode 40 includes two upper electrodes 41, 42 spaced apart from each other by a distance d on the dielectric thin film 30.

The method for manufacturing a thin film condenser 100 according to an embodiment includes forming a lower electrode 20 on a support substrate 10, forming a dielectric thin film 30 on the lower electrode 20, forming an upper electrode 40 on the dielectric thin film 30, and patterning the upper electrode 40 to form two upper electrodes 41, 42 spaced apart from each other by a distance d on the dielectric thin film 30. The method may further include polishing the back surface of the support substrate 10 to reduce the thickness of the support substrate 10.

The support substrate 10 functions as a support, and is not particularly limited as long as it has supporting capability. The support substrate 10 may provide a flat surface on which the lower electrode 20, dielectric thin film 30 and upper electrode 40 are formed in a sheet-like shape.

Particularly, the support substrate 10 may be a tabular substrate and include a material selected from metallic, ceramic, glass and plastic materials. The support substrate 10 may have high heat resistance and insulation property. More particularly, the support substrate may be amenable to slimming when polishing the back surface thereof. For example, the support substrate 10 may be selected from substrates made of silicon, glass, quartz, alumina, sapphire, strontium oxide, magnesium oxide and other metal oxides.

In addition, the support substrate 10 may have a reduced thickness through polishing or the like, after forming the lower electrode 20, dielectric thin film 30 and upper electrode 40 thereon.

The lower electrode 20 is formed on the support substrate 10, and is not particularly limited as long as it has conductive property. For example, the lower electrode 20 may be selected from metals and metal oxides.

Particularly, the lower electrode 20 may be selected from a unitary metal selected from platinum (Pt), copper (Cu), silver (Ag), gold (Au), aluminum (Al), molybdenum (Mo), tungsten (W), nickel (Ni), chrome (Cr), ruthenium (Ru), rhenium (Re), titanium (Ti) and cobalt (Co), or alloys thereof. In addition, the lower electrode 20 may be selected from a metal oxide such as LaNiO₃, ITO, AZO, LaSrCoO₃ and SrRuO₃.

More particularly, the lower electrode 20 may include one having high adhesion to the support substrate 10 among the above-listed metals and metal oxides. In a variant, as the lower electrode 20, a material having low adhesion may be used, and an adhesion reinforcing layer may be further formed between the support substrate 10 and the lower electrode 20 to enhance the adhesion to the support substrate 10.

For example, the adhesion reinforcing layer may be selected from titanium (Ti), tantalum (ta) and oxides thereof. The adhesion reinforcing layer may be inserted and formed between the support substrate 10 and the lower electrode 20. More particularly, the adhesion reinforcing layer may be formed on the support substrate 10 through deposition, before forming the lower electrode 20.

The lower electrode 20 may have a thickness of 50 nm or more. More particularly, the lower electrode 20 may have a thickness of 50 nm-3 μm. When the lower electrode 20 has a thickness less than 50 nm, it may be damaged with ease and provide an insufficient function as an electrode. When the lower electrode 20 has a thickness greater than 3 μm, it is not suitable for slimming of a thin film condenser 100.

In addition, there is no particular limitation in the method for forming the lower electrode 20. For example, the lower electrode 20 may be formed by a sputtering process, chemical vapor deposition process, pulsed laser deposition process, plating process, sol-gel process, aerosol deposition process, or the like. Particularly, a sputtering process may be used in view of productivity, cost efficiency and thin film uniformity of the thin film condenser 100.

The dielectric thin film 30 is formed on the lower electrode 20 and materials forming the dielectric thin film are not particularly limited. For example, the dielectric thin film 30 may include a currently used ferroelectric material and paraelectric material. More particularly, the material may be selected from the group consisting of ferroelectric materials such as BaTiO₃, SrTiO₃, CaTiO₃, PbTiO₃, ZrTiO₃, BaZrO₃, SrBi₂Ta₂O₉, CaZrO₃ and compounds thereof, and paraelectric materials such as SiO₂, Si₃N₄, HfO₂, Ta₂O₅, TiO₂, Al₂O₃, etc. The materials may be selected adequately depending on the particular purpose or use of the thin film condenser 100.

The dielectric thin film 30 may be formed by a sol-gel process, and the sol-gel solution used therein may have a concentration of 0.2-0.5M. Particularly, the dielectric material, such as any one of the above-listed materials, contained in the sol-gel solution may be present at a concentration of 0.2-0.5M in the solution. Such a range may improve the uniformity and characteristics of the dielectric thin film 30 when the dielectric thin film is formed by a sol-gel process.

The dielectric thin film 30 may have a thickness of 3 μm or less. More particularly, the dielectric thin film 30 may have a thickness of 50 nm-3 μm. When the dielectric thin film 30 has an excessively small thickness less than 50 nm, it is difficult to realize a condenser device due to a drop in insulation breakdown voltage and an increase in current leakage of the thin film condenser 100. On the other hand, when the dielectric thin film 30 has an excessively large thickness greater than 3 μm, the thin film condenser 100 may have poor capacitance.

There is no particular limitation in the method for forming the dielectric thin film 30. The dielectric thin film 30 may be formed by a sputtering process, chemical vapor deposition process, pulsed laser deposition process, plating process, sol-gel process, aerosol deposition process, or the like.

The upper electrode 40 is formed on the dielectric thin film 30, and is not particularly limited as long as it has conductive property. For example, the upper electrode 40 may include the same material as the lower electrode 20, and the material may be selected from the above-listed metals, metal oxides, or the like.

In addition, there is no particular limitation in the method for forming the upper electrode 40. For example, the same method as exemplified with reference to the lower electrode 20 may be used. For example, the upper electrode 40 may be formed by a sputtering process, chemical vapor deposition process, pulsed laser deposition process, plating process, sol-gel process, aerosol deposition process, or the like. Particularly, a sputtering process may be used in view of productivity, cost efficiency and thin film uniformity of the thin film condenser 100.

Further, the upper electrode 40 may have a thickness of 50 nm or more. Particularly, the upper electrode 40 may have a thickness of 50 nm-3 μm. When the upper electrode 40 has an excessively small thickness less than 50 nm, it may be damaged with ease and provide an insufficient function as an electrode. When the upper electrode 40 has a thickness greater than 3 μm, it is not suitable for slimming of a thin film condenser 100.

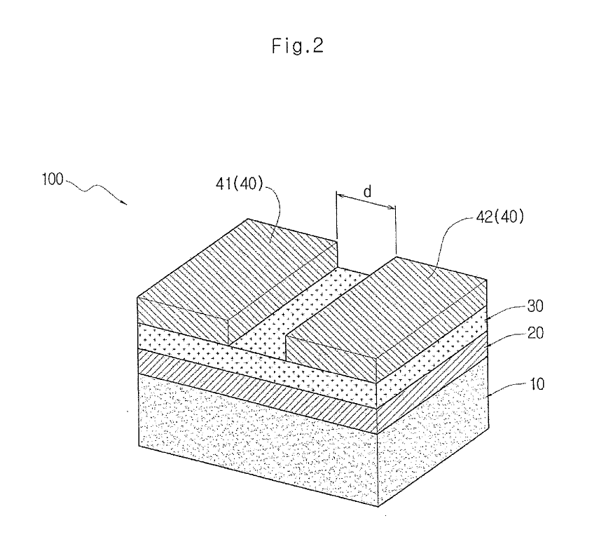

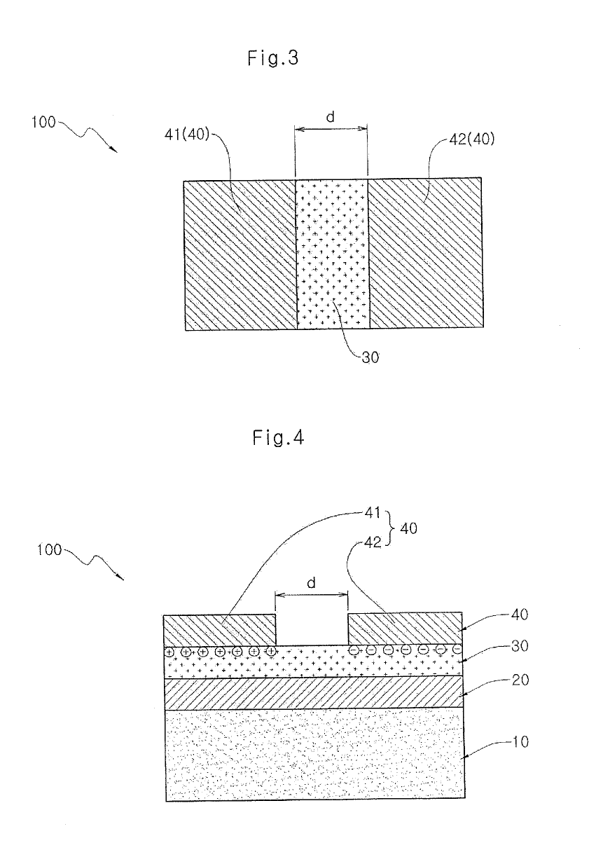

In addition, the upper electrode 40 includes two electrodes with a gap (distance) therebetween on the dielectric thin film 30. Particularly, as shown in FIG. 2 and FIG. 3, the upper electrode 40 includes two upper electrodes 41, 42 spaced apart from each other by a distance d on the dielectric thin film 30. In other words, the upper electrode 40 includes the first electrode 41 and the second electrode 42 with a predetermined distance d between the two electrodes 41, 42. There is no particular limitation in the shape and structure of each electrode 41, 42.

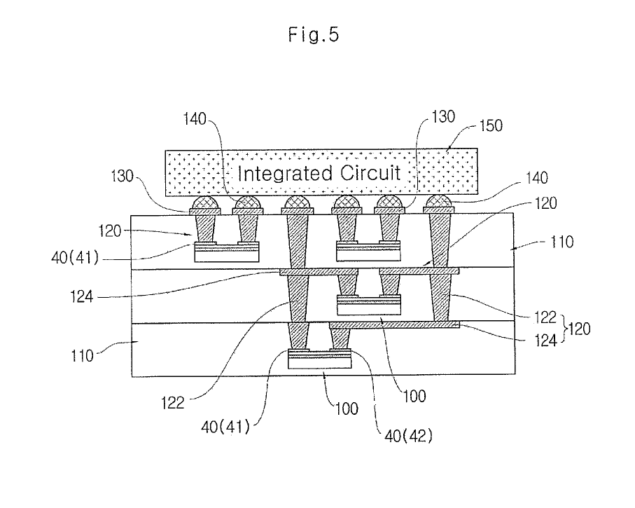

When the upper electrode 40 includes the two electrodes 41, 42, it is possible to prevent a drop in parasitic capacitance. Particularly, when the thin film condenser is packaged in a high-density package substrate, it is possible to facilitate connection with other components (see FIG. 5), and thus to improve cost efficiency and time efficiency, to realize high yield and slimming, and to improve reliability.

The two electrodes 41, 42 may be formed by patterning. For example, the patterning method, i.e., the method for forming the two electrodes 41, 42, may be selected from a direct method using a shadow mask and an electrode forming method using photolithography and etching.

Particularly, a shadow mask patterned to allow formation of the two electrodes 41, 42 is prepared, the shadow mask is positioned on the dielectric thin film 30, and the above-mentioned conductive material, such as metal or metal oxide, is deposited to perform patterning. In a variant, after the upper electrode 40 is formed through deposition, or the like, the upper electrode is etched through photolithography and etching to carry out patterning so that the two electrodes 41, 42 may be formed. More particularly, the patterning using photolithography and etching may be used in view of reliability and yield of the thin film condenser 100.

After the upper electrode 40 is patterned through the above-described process, the support substrate 10 may be polished to reduce the thickness thereof. Particularly, the back surface (the surface opposite to the surface on which the lower electrode 20 is formed (the lower surface in the figures)) of the support substrate 10 is polished (etched) physically or chemically so that the support substrate may have a minimized thickness. Such a decrease in thickness of the support substrate 10 may contribute to fabrication of an ultraslim thin film condenser 100.

The thin film condenser 100 having the above-described structure has improved capacitance and dielectric properties as compared to the surface mounting condensers according to the related art. Also, it has a simple structure, is obtained by a simple process, and is embedded (packaged) in a high-density package substrate with ease.

Referring to FIG. 4, the capacity of the thin film condenser 100 disclosed herein may be represented by the charge storage amount of both ends of the upper electrode 40, i.e., the charge storage amount of the first electrode 41 and the second electrode 42. The lower electrode 20 serves as a floating electrode. The lower electrode 20 also serves to connect both ends of the upper electrode 40. In other words, the lower electrode 20 serves to connect the first electrode 41 and the second electrode 42 formed on the dielectric thin film 30 with each other.

In addition, the capacitance of the thin film condenser 100 disclosed herein may be depicted by the following Mathematical Formula 1:

$$C = {ε}_{0} {ε}_{r} \frac{{A}_{t}}{2 d} \qquad [ Mathematical Formula 1 ]$$

wherein C is the capacitance of the thin film condenser 100, ∈₀ is the dielectric constant under vacuum, ∈ᵣ is the relative dielectric constant. In addition, Aₜ is the contact area of any one of the two upper electrodes 40 that is in contact with the dielectric thin film 30. In other words, Aₜ is the contact area of any one selected from the first electrode 41 and the second electrode 41 that is in contact with the dielectric thin film 30. Further, d is the thickness of the dielectric thin film 30.

To increase the capacitance C, the distance d between the two electrodes 41, 42 may be reduced to increase the contact area between the two electrodes 41, 42 and the dielectric thin film 30, or the thickness of the dielectric thin film 30 may be reduced. However, when the distance d between the two electrodes 41, 42 is too small, insulation breakdown voltage is degraded. On the other hand, when the distance d is too large, the thin film condenser 100 has a decreased capacity. Considering this, the distance d may be 2 μm-100 μm.

Further, in the thin film condenser 100 disclosed herein, the dielectric thin film 30 may have a twice increased thickness. In other words, since two electrodes 41, 42 are formed on one layer of dielectric thin film 30, it is possible to obtain the same effect as the presence of two layers of dielectric thin films 30 between the two electrodes 41, 42. Thus, it is possible to satisfy a predetermined insulation breakdown voltage even with a thin film having a smaller thickness. As a result, it is possible to fabricate an ultraslim thin film condenser 100.

There is no particular limitation in the shape and size of the thin film condenser 100. As shown in the perspective view of FIG. 2, the thin film condenser may have a rectangular planar shape and the same dimension as the commercially available multilayer ceramic condensers (MLCC). This allows the existing commercial producers to apply the thin film condenser as a condenser for packaging. For example, the thin film condenser may have a general dimension which is the same as currently used condenser having a size of 1005 (1 mm×0.5 mm), 0604 (0.6 mm×0.4 mm), 0402 (0.4 mm×0.2 mm).

The thin film condenser 100 disclosed herein is embedded (packaged) in the conventional high-density package substrate and connected to parts forming the same. Particularly, the thin film condenser may be embedded in the high-density package substrate of the present disclosure as described hereinafter in view of packaging efficiency. Hereinafter, the high-density package substrate will now be described.

The high-density package substrate has the thin film condenser 100 embedded therein. FIG. 5 shows the high-density package substrate according to an embodiment. As mentioned earlier, the thin film condenser 100 disclosed herein provides a higher packaging effect per unit area (or volume) as compared to the currently used surface mounting condenser.

Referring to FIG. 5, the high-density package substrate includes stacked substrates 110, a plurality of thin film condensers 100 embedded in the stacked substrates 110, an internal connection electrode 120 formed in the stacked substrates 110, a surface electrode 130 connected to the internal connection electrode 120, and an integrated circuit 150 connected to the surface electrode 130 via a bump 140. The bump 140 and the integrated circuit 150 have the same structures as generally known in the art.

Particularly, the high-density package substrate includes at least two stacked substrates 110. For example, the high-density package substrate may include 2-10 stacked substrates 110. More particularly, it may include 2-5 stacked substrates 110. The substrates 110 are stacked vertically. In FIG. 5, it is shown that three substrates 110 are stacked.

The stacked substrates 110 may be any substrates capable of embedding the thin film condenser 100, and include an insulating material. Herein, one or more thin film condensers 100 may be embedded in one stacked substrate 110. Therefore, at least two thin film condensers 100 are embedded through the stacked substrates 110 in the high-density package substrate disclosed herein. There is no limitation in number of the embedded thin film condensers 100, and various numbers of thin film condensers may be selected as desired. For example, 5-200 thin film condensers 100 may be embedded.

In addition, the thin film condensers 100 may be connected with each other in series or in parallel. Particularly, the thin film condensers 100 are connected with each other in series or in parallel through the internal connection electrode 120 formed in the stacked substrates 110.

As shown in FIG. 5, the internal connection electrode 120 may include a vertical connection electrode 122 formed along the vertical direction in the stacked substrates 110, and a horizontal connection electrode 124 formed along the horizontal direction in the stacked substrates 110. As also shown in FIG. 5, the vertical connection electrode 122 may be connected to the upper electrode 40 of each thin film condenser 100. In addition, the horizontal connection electrode 124 may make a connection with one vertical connection electrode 122 with another. Further, the vertical connection electrode 122 may make a connection between one upper electrode 40 (i.e., the first electrode 41) of one thin film condenser 100 and one upper electrode (i.e., the first electrode) of another thin film condenser to accomplish a connection in parallel, and the horizontal connection electrode 124 may make a connection in series.

In addition, the outermost substrate 110 among the stacked substrates 110 (i.e., the substrate 110 positioned at the uppermost part in FIG. 5) has a surface electrode 130 on the top thereof. The surface electrode 130 is connected with the internal connection electrode 120. The surface electrode 130 is connected to the integrated circuit 150 by way of the bump 140. In other words, the bump 140 is formed on the top of the surface electrode 130, and the bump 140 connects the surface electrode 130 with the integrated circuit 150. As a result, the thin film condensers 100 are connected to the integrated circuit 150 in series or in parallel.

Therefore, the high-density package substrate having the above described structure allows high-density packaging while the thin film condensers 100 are connected with each other from side to side in series or in parallel. Thus, it is possible to provide a high packaging effect per unit area (or volume) and to realize a slimmed structure. In addition, the two electrodes 41, 42 of the thin film condensers 100 are connected to the integrated circuit 150 through the internal connection electrode 120, thereby reducing the connection length between one device and another device. As a result, it is possible to reduce electrical parasitic components and to improve electrical performance.

As can be seen from the foregoing, the thin film condenser having a simple structure as disclosed herein is embedded easily in a high-density package substrate without changing the electrical and physical properties of the high-density package substrate. In addition, unlike the thin film condenser for high-density packaging having a complicated structure according to the related art, the thin film condenser disclosed herein has not only a simple structure but also excellent capacitance and dielectric properties, and thus ensures high reliability. Further, by virtue of such a simple structure, the thin film condenser disclosed herein is manufactured by a simple process at low cost, thereby providing high cost efficiency. In addition to the above, the thin film condenser disclosed herein has excellent electrical performance due to such a decreased connection length between one device and another device.

The examples will now be described. The following examples are for illustrative purposes only and not intended to limit the scope of the present disclosure.

### EXAMPLES

In the following examples, a silicon (Si) substrate having a silicon dioxide (SiO₂) layer formed on the surface thereof to a thickness of 300 nm is used as a support substrate to provide the thin film condenser in accordance with each example.

<Deposition of Lower Electrode>

To form the lower electrode of a thin film condenser, a platinum (Pt) electrode is formed on the top of the support substrate via DC-sputtering. Herein, titanium is deposited between the lower electrode and the support substrate to a thickness of 50 nm in order to enhance the adhesion between the support substrate and the lower electrode. Particularly, a 4-inch Ti target is used to deposit Ti on the SiO₂ layer of the support substrate, and Ti is deposited at a power level of 30 W for 20 minutes, after maintaining a vacuum state of 5 mtorr under argon (Ar) gas atmosphere. Then, a 4-inch Pt target is used and a Pt lower electrode is deposited on the Ti deposition layer via sputtering at a power level of 30 W for 8 minutes, after maintaining a vacuum state of 5 mtorr under Ar gas atmosphere.

<Preparation Example of Sputtering Target for Dielectric Thin Film>

To form a dielectric thin film by using RF-sputtering, a BaTiO₃ target and a Ba_{0.6}Sr_{0.4}TiO₃ target, each having a size of 2 inches, are provided as follows.

First, to provide a BaTiO₃ target, BaCO₃ with a purity of 99.99% and TiO₃ powder with a purity of 99.99% are mixed with each other in a molar ratio of 1:1. To perform the mixing, powder is introduced to a cylindrical container made of polypropylene (PP) together with zirconia balls and ethanol, and the resultant mixture is milled at 160 rpm for 24 hours. Then, the milled powder is dried in an oven at 100° C. for 6 hours to remove ethanol therefrom, and a zirconia mortar is used to pulverize entangled powder uniformly.

Then, the powder is introduced to an alumina crucible and heat treated at a temperature of 1,000° C. for 4 hours to obtain BaTiO₃. Since the obtained BaTiO₃ powder has crude and non-uniform particles, they are further pulverized by using a zirconia mortar. In addition, ethanol is introduced to a PP container together with zirconia balls to perform milling at 160 rpm for 24 hours. Then, the resultant powder is dried in an oven at 100° C. for 6 hours to remove ethanol therefrom. To prevent cracking during molding, 5 wt % solution of polyvinyl alcohol is added to the powder as a binder, and then the powder is screened with a sieve to obtain a uniform particle size. The screened powder is introduced to a 3-inch mold and pressurized under a pressure of 20 tons for 1 minute to obtain a molded product, which, in turn, is heat treated at 600° C. for 4 hours to remove the binder therefrom. Then, to enhance densification of the molded target from which the binder is removed and to increase the density thereof, the molded target is sintered at 1300° C. for 2 hours. Finally, the finished sintered product is processed to a size of 2 inch and a copper plate is attached to the back surface thereof to provide a BaTiO₃ sputtering target (Preparation Example 1).

Meanwhile, to provide a Ba_{0.6}Sr_{0.4}TiO₃ target, BaCO₃ with a purity of 99.99%, SrCO₃ with a purity of 99.99% and TiO₂ powder with a purity of 99.99% are used and mixed in a molar ratio of 0.6:0.4:1. The subsequent operations are the same as described hereinabove with reference to the preparation of a BaTiO₃ target, except that the sintering operation is carried out at 1200° C. to perform densification of the molded product and to increase the density thereof. In this manner, a Ba_{0.6}Sr_{0.4}TiO₃ sputtering target is obtained (Preparation Example 2).

<Preparation Example of Sol-Gel Solution for Dielectric Thin Film>

According to another embodiment for forming a dielectric thin film, a sol-gel process is used. To obtain a Ba_{0.6}Sr_{0.4}TiO₃ solution for use in the sol-gel process, barium acetate and strontium acetate with a purity of 99.99%, and titanium isopropoxide are used. Acetyl acetonate is used as a stabilizer, and acetic acid and 2-methoxyethanol are used as solvents.

First, barium acetate, strontium acetate, titanium isopropoxide and acetyl acetonate are adjusted to a molar ratio of 0.6:0.4:1:1, and acetic acid and 2-methoxyethanol are adjusted to a weight ratio of 3:7. Next, barium acetonate and strontium acetonate are mixed in acetic acid and agitated at 120° C. for 30 minutes, while titanium isopropoxide and acetyl acetonate are mixed in 2-methoxyethanol and agitated at 120° C. for 30 minutes. Then, the two agitated solutions are mixed with each other, and further agitated at 120° C. for 1 hour to provide 0.3M Ba_{0.6}Sr_{0.4}TiO₃ solution for a sol-gel process.

### Example 1

To form a dielectric thin film on the support substrate on which the Pt lower electrode is deposited as described above, an RF-sputtering process is used. The 2-inch BaTiO₃ target obtained from Preparation Example 1 is used as a material for the dielectric thin film. To prevent the thin film from being contaminated during deposition, a high vacuum state of about 2×10⁻⁶ torr is maintained before deposition. In addition, Ar and O₂ gases are maintained at a ratio of 9:1 for the purpose of thin film deposition, and then 80 W-RF power is applied under a vacuum degree of 20 mtorr. Herein, the heater provided on the bottom of the support substrate is used to maintain a temperature of 700° C. during deposition to assist improvement of the crystallinity of the thin film.

Deposition is carried out for 50 minutes under the above-mentioned conditions to form a BaTiO₃ thin film with a thickness of about 100 nm. After the deposition, a rapid thermal annealing system is used to perform heat treatment at 800° C. for 5 minutes to improve the crystallinity of the thin film.

Then, a DC sputtering process is used to form an upper electrode on the formed BaTiO₃ thin film. A Pt upper electrode is deposited to a thickness of 100 nm under the same conditions as the deposition of the lower electrode. Next, to transform the deposited Pt upper electrode into two electrodes (i.e., to form a pattern having a predetermined gap (distance) on the Pt upper electrode), a photolithographic process is used by applying a photoresist onto the Pt upper electrode and using a photomask to carry out exposure with a UV lamp and development. After the photolithographic process, an inductive coupled plasma etching system is used to carry out dry etching.

Through the etching, two rectangular shaped Pt upper electrodes are formed with a distance of 10 μm therebetween, thereby finishing the thin film condenser according to Example 1. Three specimens having different sizes are provided in the same manner as described above.

### Example 2

To form a dielectric thin film on the support substrate on which the Pt lower electrode is deposited as described above, an RF-sputtering process is used. The 2-inch Ba_{0.6}Sr_{0.4}TiO₃ target obtained from Preparation Example 2 is used as a material for the dielectric thin film. To prevent the thin film from being contaminated during deposition, a high vacuum state of about 2×10⁻⁶ torr is maintained before deposition. In addition, Ar and O₂ gases are maintained at a ratio of 8:2 for the purpose of thin film deposition, and then 80 W—RF power is applied under a vacuum degree of 20 mtorr. Herein, the heater provided on the bottom of the support substrate is used to maintain a temperature of 700° C. during deposition to assist improvement of the crystallinity of the thin film.

Deposition is carried out for 65 minutes under the above-mentioned conditions to form a Ba_{0.6}Sr_{0.4}TiO₃ thin film with a thickness of about 100 nm. After the deposition, a rapid thermal annealing system is used to perform heat treatment at 800° C. for 5 minutes to improve the crystallinity of the thin film, in the same manner as Example 1.

Then, a DC sputtering process is used to form an upper electrode on the formed Ba_{0.6}Sr_{0.4}TiO₃ thin film. A Cu electrode is deposited to a thickness of 200 nm under the same conditions as the deposition of the lower electrode. Next, to form a pattern having a predetermined gap (distance) on the Pt upper electrode, a photolithographic process is used by applying a photoresist and using a photomask to carry out exposure with a UV lamp and development. After the photolithographic process, the portions where PR is developed are etched by using a ferric chloride solution.

Through the etching, two rectangular shaped Cu upper electrodes are formed with a distance of 10 μm therebetween, thereby finishing the thin film condenser according to Example 2. Three specimens having different sizes are provided in the same manner as described above.

### Example 3

To form a dielectric thin film on the support substrate on which the Pt lower electrode is deposited as described above, a sol-gel process is used. The Ba_{0.6}Sr_{0.4}TiO₃ solution for a sol-gel process obtained from the above Preparation Example is used as a material for the dielectric thin film. First, the Ba_{0.6}Sr_{0.4}TiO₃ solution is dropped onto the support substrate and spin-coated at 500 rpm for 5 seconds and at 4000 rpm for 30 seconds, followed by drying at 150° C. for 5 minutes to remove the solvents. Then, to remove the remaining organic materials, heat treatment is carried out at 350° C. for 10 minutes to form an amorphous Ba_{0.6}Sr_{0.4}TiO₃ thin film. It is required that the amorphous Ba_{0.6}Sr_{0.4}TiO₃ thin film is converted into a multicrystalline thin film to increase the dielectric constant of the thin film. For this, a rapid thermal annealing system is used to perform heat treatment at 800° C. for 5 minutes.

Then, a DC sputtering process is used to form an upper electrode on the formed Ba_{0.6}Sr_{0.4}TiO₃ thin film. A Cu electrode is deposited to a thickness of 200 nm under the same conditions as the deposition of the lower electrode. Next, to form a pattern having a predetermined gap (distance) on the Pt upper electrode, a photolithographic process is used by applying a photoresist and using a photomask to carry out exposure with a UV lamp and development. After the photolithographic process, the portions where PR is developed are etched by using a ferric chloride solution.

Through the etching, two rectangular shaped Cu upper electrodes are formed with a distance of 10 μm therebetween, thereby finishing the thin film condenser according to Example 3. Three specimens having different sizes are provided in the same manner as described above.

<Evaluation of Capacitance and Dielectric Properties of Thin Film Condensers>

Each of the thin film condensers for high-density packaging according to Examples 1-3 is determined for capacitance and dielectric characteristics (dielectric loss) at 1 kHz. The results are shown in the following Table 1. The dielectric properties are determined by using an impedance analyzer. In Table 1, the condenser size ‘0402’ means 0.4 mm×0.2 mm (width×length), ‘0604’ means 0.6 mm×0.4 mm (width×length), and ‘1005’ means 1 mm×0.5 mm (width×length).

TABLE 1
Results of Evaluation of Capacitance and Dielectric
Properties of Thin Film Condensers

| | | Method of | | | | |
|---|---|---|---|---|---|---|
| | | Forming | | | | Dielectric |
| | Dielectric | Dielectric | Condenser | Capacitance | | Loss (%) |
| | Material | Thin Film | Size | (@ 1 kHz) | | (@ 1 kHz) |
| Ex. | BaTiO₃ | RF- | 0402 | 0.46 | nF | 3.1 |
| 1-1 | | sputtering | | | | |
| Ex. | BaTiO₃ | RF- | 0604 | 1.37 | nF | 3.3 |
| 1-2 | | sputtering | | | | |
| Ex. | BaTiO₃ | RF- | 1005 | 2.86 | nF | 3.6 |
| 1-3 | | sputtering | | | | |
| Ex. | Ba_{0.6}Sr_{0.4}TiO₃ | RF- | 0402 | 1.3 | nF | 2.3 |
| 2-1 | | sputtering | | | | |
| Ex. | Ba_{0.6}Sr_{0.4}TiO₃ | RF- | 0604 | 3.95 | nF | 2.7 |
| 2-2 | | sputtering | | | | |
| Ex. | Ba_{0.6}Sr_{0.4}TiO₃ | RF- | 1005 | 8.22 | nF | 2.5 |
| 2-3 | | sputtering | | | | |
| Ex. | Ba_{0.6}Sr_{0.4}TiO₃ | sol-gel | 0402 | 0.6 | nF | 2.0 |
| 3-1 | | | | | | |
| Ex. | Ba_{0.6}Sr_{0.4}TiO₃ | sol-gel | 0604 | 1.81 | nF | 1.9 |
| 3-2 | | | | | | |
| Ex. | Ba_{0.6}Sr_{0.4}TiO₃ | sol-gel | 1005 | 3.76 | nF | 2.3 |
| 3-3 | | | | | | |

As shown in Table 1, as the condenser size increases (i.e., as the area of condenser increases), capacitance also increases. It can be seen that when a Ba_{0.6}Sr_{0.4}TiO₃ thin film is formed by RF-sputtering, the highest capacitance and excellent dielectric properties are obtained.

Meanwhile, in addition to the above examples, it is possible to obtain thin film condensers for high-density packaging having different capacities of 1 pF to 10 nF as in the case of commercially available condensers through a simple process at low cost by varying the dielectric material in a condenser or by controlling the thickness and area of a condenser.

While the exemplary embodiments have been shown and described, it will be understood by those skilled in the art that various changes in form and details may be made thereto without departing from the spirit and scope of the present disclosure as defined by the appended claims.

What is claimed is:

1. A thin film condenser for high-density packaging, comprising:
a support substrate;
a lower electrode formed on the support substrate;
a dielectric thin film formed on the lower electrode; and
an upper electrode formed on the dielectric thin film,
wherein the upper electrode comprises two electrodes spaced apart from each other by a predetermined distance on the dielectric thin film.

2. The thin film condenser for high-density packaging according to claim 1, wherein the predetermined distance is 2 μm-100 μm

3. The thin film condenser for high-density packaging according to claim 1, wherein the lower electrode has a thickness of 50 nm-3 μm.

4. The thin film condenser for high-density packaging according to claim 1, wherein the dielectric thin film has a thickness of 50 nm-3 μm.

5. A method for manufacturing a thin film condenser for high-density packaging, comprising:
forming a lower electrode on a support substrate;
forming a dielectric thin film on the lower electrode;
forming an upper electrode on the dielectric thin film; and
patterning the upper electrode to form two electrodes spaced apart from each other by a predetermined distance on the dielectric thin film.

6. The method for manufacturing a thin film condenser for high-density packaging according to claim 5, which further comprises, after patterning the upper electrode, polishing the back surface of the support substrate to reduce the thickness of the support substrate.

7. The method for manufacturing a thin film condenser for high-density packaging according to claim 5, wherein the dielectric thin film is formed to have a thickness of 50 nm-3 μm.

8. A high-density package substrate, comprising:
at least two stacked substrates;
the thin film condensers as defined in claim 1, embedded in the stacked substrates;
an internal connection electrode formed in the stacked substrates and connecting the thin film condensers in series or in parallel;
a surface electrode formed on the surface of the outermost substrate among the stacked substrates and connected to the internal connection electrode; and
an integrated circuit connected to the surface electrode via a bump.

9. The high-density package substrate according to claim 8, wherein the internal connection electrode comprises a vertical connection electrode formed along the vertical direction in the stacked substrates, and a horizontal connection electrode formed along the horizontal direction in the stacked substrates.
